(19) United States
(12) Patent Application Publication
(10) Pub. No.: US 2013/0100654 A1
(43) Pub. Date: Apr. 25, 2013

(54) COMPLEMENTARY CONFIGURATION OF MOUNTED LIGHT SOURCES

(71) Applicants: Alexandre David Bourdois, North Attleboro, MA (US); Johnny T. Hendrix, Medfield, MA (US)

(72) Inventors: Alexandre David Bourdois, North Attleboro, MA (US); Johnny T. Hendrix, Medfield, MA (US)

(21) Appl. No.: 13/657,909

(22) Filed: Oct. 23, 2012

Related U.S. Application Data
(60) Provisional application No. 61/550,428, filed on Oct. 23, 2011.

(51) Int. Cl. F21V 21/00; H01L 33/48; F21L 4/02

(52) U.S. Cl. 362/184; 362/249.02; 438/28; 257/E33.056

(57) ABSTRACT

At a first location on a first portion of a mounting interface, a mounted first light source comprises a first light emitting diode and a mounting surface electrically coupled to an anode of the first light emitting diode; and at a second location on the first portion of the mounting interface, a mounted second light source comprises a second light emitting diode and a mounting surface electrically coupled to a cathode of the second light emitting diode. The mounting connections provide thermal conductivity between the first portion and the mounting surface of the first light source and between the first portion and the mounting surface of the second light source, and provide an electrical connection between the anode of the first light emitting diode and the cathode of the second light emitting diode.

### CROSS-REFERENCE TO RELATED APPLICATIONS

This application claims the benefit of U.S. Provisional Application No. 61/550,428, filed Oct. 23, 2011, incorporated herein by reference.

### BACKGROUND

This description relates to complementary configuration of mounted light sources.

Light Emitting Diodes (LEDs) have great potential for lighting and other applications as they offer higher efficiency than many other lighting technologies, including the popular incandescent and fluorescent technologies. LED technology continues to rapidly improve in both efficacy, measured in lumens per watt (lm/W), and in lower cost higher yield manufacturing. For example, the average efficacy of a white LED improved from less than 40 lm/W to over 140 lm/W (in laboratory devices) in just a few years. During this same period the LED light bulb also emerged. The initial commercially available LED light bulbs produced used many LEDs to provide adequate light output, but LED light bulbs have evolved such that many bulbs are produced using fewer high power LEDs. For example, there are 40-60 W incandescent equivalent LED bulbs with as few as four or five high power LEDs, and this number may go down as the LEDs improve.

### SUMMARY

In one aspect, in general, an apparatus, comprises: a first light source comprising a first light emitting diode and a mounting surface electrically coupled to an anode of the first light emitting diode; a second light source comprising a second light emitting diode and a mounting surface electrically coupled to a cathode of the second light emitting diode; and a mounting interface having a first portion configured to support a connection to the mounting surface of the first light source at a first location on the first portion, and configured to support a connection to the mounting surface of the second light source at a second location on the first portion. The connections provide thermal conductivity between the first portion and the mounting surface of the first light source and between the first portion and the mounting surface of the second light source, and the connections provide an electrical connection between the anode of the first light emitting diode and the cathode of the second light emitting diode.

In another aspect, in general, a method comprises: providing a mounting interface; connecting, at a first location on a first portion of the mounting interface, a first light source comprising a first light emitting diode and a mounting surface electrically coupled to an anode of the first light emitting diode; and connecting, at a second location on the first portion of the mounting interface, a second light source comprising a second light emitting diode and a mounting surface electrically coupled to a cathode of the second light emitting diode. The connections provide thermal conductivity between the first portion and the mounting surface of the first light source and between the first portion and the mounting surface of the second light source, and the connections provide an electrical connection between the anode of the first light emitting diode and the cathode of the second light emitting diode.

Aspects can include one or more of the following features.

The first portion of the mounting interface comprises an electrically conductive material.

The first portion comprises a surface of the electrically conductive material.

The first portion comprises a substantially flat surface of the electrically conductive material.

The mounting surface of the first light source and the mounting surface of the second light source are substantially flat.

The surface of the electrically conductive material has at least one bend between the first location and the second location to provide an angle between the mounting surface of the first light source and the mounting surface of the second light source.

The electrically conductive material consists essentially of metal.

The mounting interface includes a second portion that is electrically insulating and configured to electrically isolate a terminal electrically coupled to a cathode of the first light emitting diode and configured to electrically isolate a terminal electrically coupled to an anode of the second light emitting diode.

A power source is electrically coupled to: the terminal electrically coupled to the cathode of the first light emitting diode, and the terminal electrically coupled to the anode of the second light emitting diode.

The first light emitting diode is fabricated on a first surface of a first semiconductor substrate and the mounting surface of the first light source comprises a metalized surface of the first semiconductor substrate opposite to the first surface of the first semiconductor substrate, and the second light emitting diode is fabricated on a first surface of a second semiconductor substrate and the mounting surface of the second light source comprises a metalized surface of the second semiconductor substrate opposite to the first surface of the second semiconductor substrate.

The first semiconductor substrate is doped as a p-type semiconductor, and the second semiconductor substrate is doped as an n-type semiconductor.

At least one of the first light source or the second light source includes multiple light emitting diodes.

A third light source comprises a third light emitting diode and a mounting surface electrically coupled to an anode of the third light emitting diode, and a fourth light source comprises a fourth light emitting diode and a mounting surface electrically coupled to a cathode of the fourth light emitting diode; and the mounting interface has multiple electrically isolated portions, including the first portion and a second portion configured to support a connection to the mounting surface of the third light source at a first location on the second portion, and configured to support a connection to the mounting surface of the fourth light source at a second location on the second portion. The connections provide thermal conductivity between the second portion and the mounting surface of the third light source and between the second portion and the mounting surface of the fourth light source, and the connections provide an electrical connection between the anode of the third light emitting diode and the cathode of the fourth light emitting diode.

An electrical connection is provided between a terminal electrically coupled to the anode of the second light emitting diode and the cathode of the third light emitting diode.

The first light source, second light source, and mounting interface are included in a single surface mount package.

The first light source, second light source, and mounting interface are fabricated in a single manufacturing process.

Aspects can have one or more of the following advantages.

Configurations of the LEDs in lighting systems may take on many forms. For example, one configuration is a series string of LEDs, and some configurations use multiple LED strings or even combinations of series/parallel arrangements. The selection of the configuration may depend on the light output power required and the complexity of the electronic driver and the application.

LED packaging technology has also evolved from small all clear plastic bodies to larger die and packages to accommodate higher light output and power dissipation. These higher power LED packages often have thermal management systems to help move the heat rapidly from the LED's junction to the LED's mounting base (base terminal). The base terminal is the surface of device that enables the device to be soldered down to a printed circuit board (PCB) or other types of circuit interfaces. Some high power LED devices available are in surface mount (SMT) packages. These are packages where the anode and cathode terminals are typically planar to the bottom of the package so that the terminals can be directly connected to the pads of a printed circuit board. Other high power SMT package options include leadless devices where the anode and cathode terminals are both under the package so that the package can be directly soldered to the PCB type board.

Some LED lighting systems include multiple LEDs, a power supply, and a thermal management system. The thermal management system may include a heat-sink used to move the heat generated by the LEDs to the open environment. Managing the LEDs' temperature from excessive heat is a factor for longer life and reliability. LED lighting system efficiency may also be higher when some or all of the LEDs are connected in series arrangements as opposed to parallel arrangements, since for any given output power level, the power supply is more efficient at delivering lower currents at higher voltages than higher currents at lower voltages. One reason for this is that conduction losses (UR) through the various power supply elements are more dominant at higher currents. Series string arranged LEDs may also be simpler to drive, and in some arrangements there is only one current loop that requires regulation.

Some LED lighting systems use printed circuit boards (PCB) to support and electrically connect the LEDs in an electrical series string. For low cost low power applications fiberglass (e.g., FR4 fiberglass) may be used as PCB material. For higher power applications often found in general LED lighting systems, the use of more elaborate PCB materials such as metal clad PCBs that have a metal substrate, including insulated metal substrate (IMS) or Direct Bonded Copper (DBC) PCBs, may be used. The term PCB is used as a general categorization of the described PCB technologies. Some materials are preferred because they have better thermal conductivity characteristics than other materials (e.g., FR4 fiberglass), but these materials may have higher cost, both for the cost of the material itself and for the cost of the circuit layout.

Some embodiments enable the circuit board that supports the LEDs in the lighting system to be eliminated. For example, the LEDs can be configured to be mounted on a metal object in the lighting system, enabling significant cost reductions and better thermal conductivity. If an LED lighting system (e.g., a bulb) were available for lower cost, it would be advantageous to the end user and energy conservation goals alike to replace older generation bulbs to save more on energy costs by taking advantage of efficiency improvements in LED technology.

In some embodiments, two uniquely different LEDs are configured to enable an electrical series connection between them to form a series pair. For example, the mounting structure of each of the LEDs in the pair may enable a series connection when the LEDs are affixed to the same metal object. In some embodiments, there is no need for a circuit board in the lighting system that supports and connects LEDs, saving costs, while also providing a superior thermal conduction path for the heat generated by the LEDs to be removed and released to the exterior environment.

For example, a series circuit coupling of two LEDs is formed when the base terminal of each LED is affixed to the same metal object. In one example, each of the two LED devices, with respect to the each other, are complementary such that they constructed or arranged with each LED having opposite electrodes at the base terminal, one LED having the anode terminal as the base terminal, and the other LED having the cathode terminal as the base terminal. When the two dissimilar LED's base terminals are affixed to the same metal base mounting structure it creates a series pair. The circuit is complete when the pair's two remaining uncoupled terminals, anode and cathode, are coupled to a power source in the proper polarity. This LED pair formation can apply to LEDs in die/chip or packaged forms. The metal object could be any structure of any shape or size, and can have any number of bends or folds, and couples the two LEDs of the pair in series.

Other features and advantages of the invention are apparent from the following description, and from the claims.

### DESCRIPTION OF DRAWINGS

FIG. 1 is a diagram of a complementary source lighting system.

FIG. 2 is a circuit schematic of a complementary source lighting system.

FIGS. 3A, 3B, and 4 are diagrams of examples of devices with complementary LEDs.

FIG. 5 is drawing of a light bulb with complementary LEDs.

FIGS. 6A, 6B, 7A, and 7B are diagrams of examples of complementary configurations of LEDs.

FIG. 8 is a diagram of a multi-leg bridge device.

FIG. 9 is diagram of a device with multiple pairs of complementary LEDs in isolated sections.

### DESCRIPTION

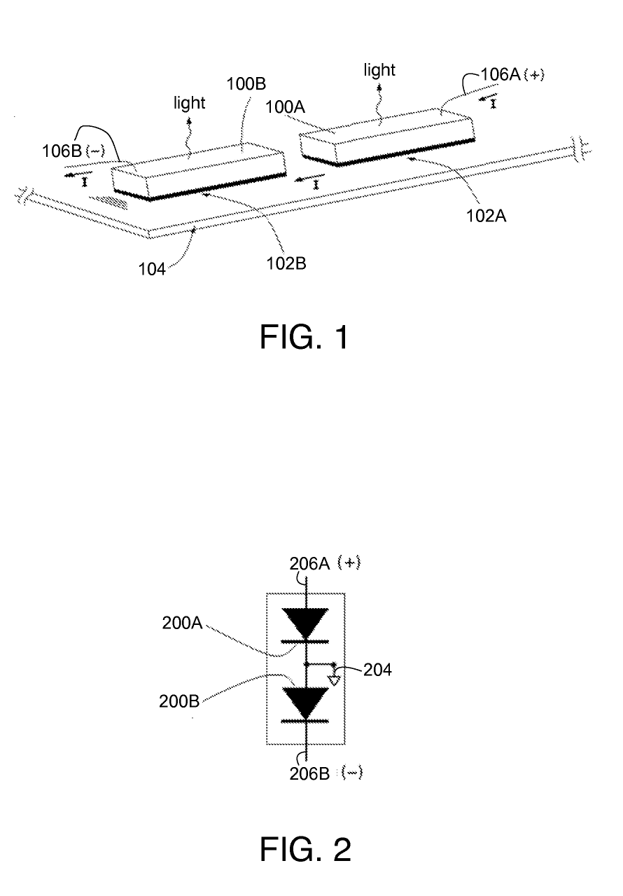

Referring to FIG. 1, an example of a complementary source lighting system includes two LEDs 100A, 100B (e.g., either in die/chip or packaged forms) with each having opposite terminals at the base terminal. LED 100A has a Cathode base terminal 102A, and LED 100B has an Anode base terminal 102B. For each of these LEDs, the base terminal is an electrically conductive material in contact with the surface of the LED (e.g., a semiconductor substrate on which the LED is fabricated). In this example, the LEDs are attached to a mounting interface for any of a variety of applications (e.g., a lighting system). In some implementations, the mounting interface includes a conductive (e.g., metal) plate 104 that provides support for the LEDs and acts as an electrical and thermal coupler. In other implementations, the mounting interface can be any shape of metal object or other material that provides both high electrical conductivity and high thermal conductivity. The attachment of the base terminals to the plate 104 can be solder, electrically conductive epoxy, for example, or some other method that secures the LED devices to the plate 104 and provides a low resistance path, both electrically and thermally. The LED 100A has an uncoupled Anode terminal 106A, and the LED 100B has an uncoupled Cathode terminal 106B. The uncoupled terminals are marked in FIG. 1 by polarity (+)(−), and are kept isolated from all other electrical terminals including the plate 104 and are connected to a power source output (not shown). The uncoupled anode and cathode terminals can be leads, bond-wires, bus bar, circuit board, for example, or any method that routes them to the power source.

FIG. 2 shows the electrical equivalent of the LED pair of FIG. 1, with top LED 200A representing LED 100A and bottom LED 200B representing LED 100B. The Anode terminal 206A of the top LED 200A and cathode terminal 206B of the bottom LED 200B are kept electrically isolated from the conductive mounting interface, which is represented by common symbol 204, and are routed to a power source in forward bias polarity so as to emit light. The use of the common symbol in FIG. 2 does not necessarily imply any ground—it is used to identify an electric common with the three objects (Cathode base terminal 102A, Anode base terminal 102B, and supporting plate 104).

LED die products available from different LED manufactures can be fabricated using different technologies, where some LED technologies (e.g., from manufacturer Cree) produce LED die with the Cathode terminal at the bottom or mounting surface of the die, while other LED technologies (e.g., from manufacturer LatticePower) produce LED die with the Anode terminal at the bottom or mounting surface of the die. Affixing one of each of these two different type LEDs directly to a conductive mounting interface, as described with reference to FIG. 1, would make a complementary LED pair as each device has opposite electrodes at their mounting surface. Applying these die directly to a conductive mounting interface would also maximize thermal conductivity to more effectively manage the heat created by the LEDs. The two die could be packaged together as an LED pair or packaged individually where one die of each technology type is used to create the pair. Individually packaged LEDs would not require a dielectric barrier between the die and metal package carrier that supports the die in the package as the other side of the LED's metal carrier is the bottom of the package, mounting surface. The advantage of not needing to apply a dielectric barrier either in the package or externally is the direct, die to metal carrier, to conductive mounting interface coupling, that optimizes thermal conductivity so that heat generated by the LEDs can be moved with little thermal resistance.

In some implementations, to optimize LED thermal management with the LEDs in die/chip or packaged forms, an LED chip design, process, or technology, could be used produce one LED die that has a bottom side (mounting side) directly metalized to the p-type substrate (e.g., with an ohmic contact), and the other LED in the pair having a metalized n-type substrate bottom, or other substrate combination that makes each LED in the pair have opposite terminals, one having anode and the other having cathode as the mounting side contact. The two LED devices can each be from different technologies to facilitate the formation of the pair with opposite base terminal contacts. In packaged form the metalized mounting surface of the die, with no dielectric barrier, can be affixed to metal, such as the packages carrier surface where the opposite side of the carrier is the package's mounting side or bottom.

In some implementations, for LED technologies that have non-ohmic substrate with dielectric properties such as sapphire, metallization techniques for metalizing die surfaces and contacts at the die level can be used to make structures that support electrical connections that can route either electrode contact to the LED's chip mounting surface (which electrode is routed to the base depends on which in the pair is being produced). This provides one in the pair that has an anode base mounting contact terminal, while the other has a cathode for the base mounting contact terminal.

In some implementations, the packaging of the LED pair can include fabricating the LED devices into a single package. In this case the mounting interface, as described in FIG. 1, can be considered the metal carrier in the package where the opposite surface of the metal carrier is now the base mounting surface.

In some implementations, the LED manufacturing processes enable the pair of LED devices to be fabricated in a single fabrication process.

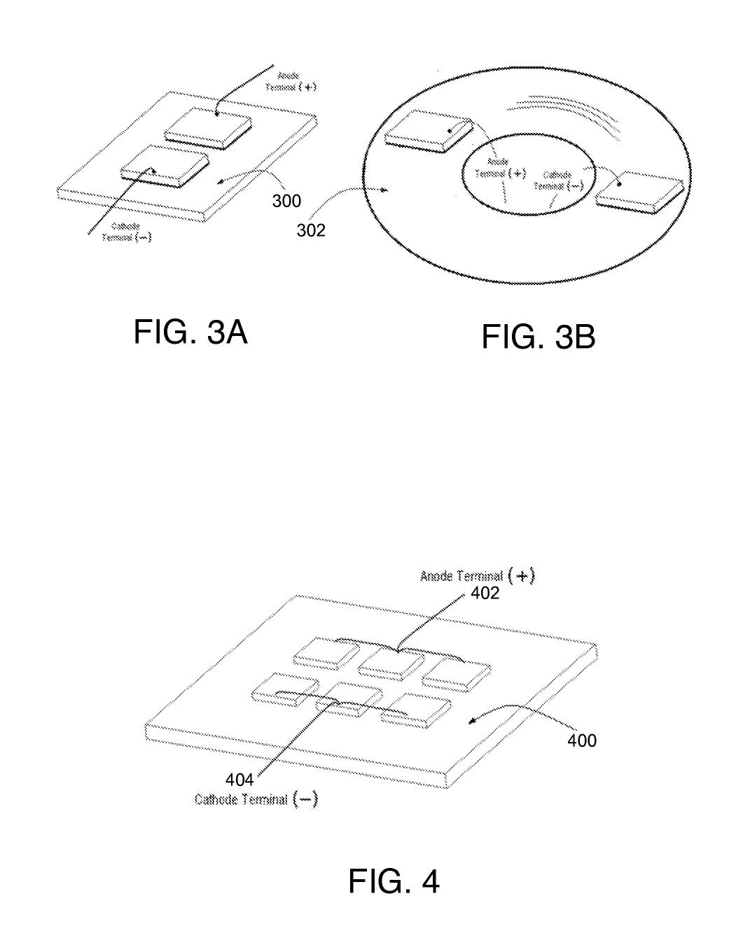

FIGS. 3A and 3B show examples of the various shapes the LED's conductive mounting interface can be. The mounting interface can include a flat or planar conductive portion where the package or die lay to increase heat conduction from the LED die to mounting surface, but the conductive portion can be any shape, have bends, in any length. FIG. 3A shows a rectangular conductive plate 300 as the mounting interface. FIG. 3B shows an annular conductive plate 302 as the mounting interface. The conductive portion of a mounting interface can also be formed with bends or angles to support each of two (or more) LEDs so that light from the LEDs can be directed in different directions.

FIG. 4 shows an example of a 3×2 matrix of complementary LEDs on a common mounting interface 400. This matrix is comprised of LEDs forming a series parallel arrangement or “multi-leg bridge” having a top leg with three cathode-connected (parallel) LEDs in series with a bottom leg with three anode-connected (parallel) LEDs. The anode terminals of the LEDs in the top leg are connected by conducting wires to a common anode terminal 402, and the cathode terminals of the LEDs in the bottom leg are connected by conducting wires to a common cathode terminal 404. In other examples, the number of LEDs in the top leg verses the lower leg may be different.

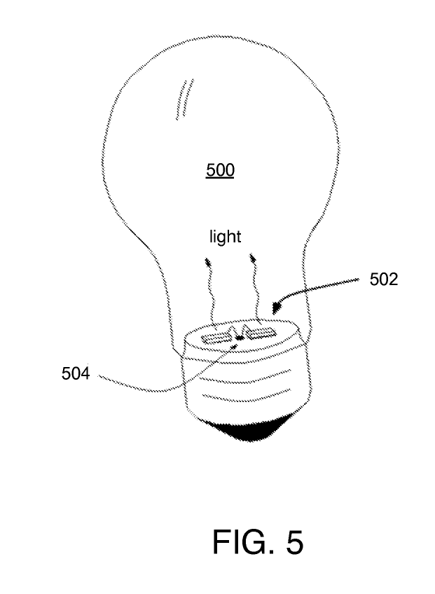

FIG. 5 shows an example of an LED light bulb 500 (e.g., as a replacement for a standard A19 light bulb), with the LED pair mounted on a metal surface 502 in the bulb. The metal surface 502 is configured with a hole 504 that is insulated to isolate leads from the uncoupled terminals of the LED pair so they can be connected to power source contacts in the base of the bulb. The complementary configuration can be used in every type of incandescent, halogen, florescent and other lighting technologies where a LED lighting equivalent or replacement is desired. The complementary configuration could be applied to LED replacement bulbs of any bulb design or form factor including lighting fixtures that are integrated with all elements of the LED lighting system including the housing, power supply, and LEDs.

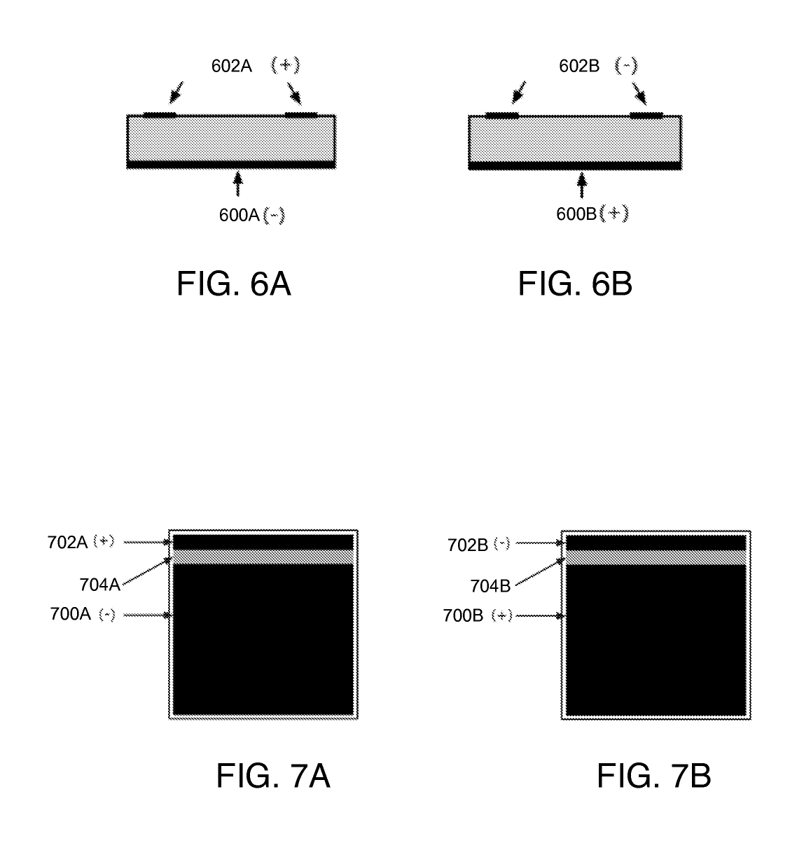

The conducting material providing terminals for an LED die can have various arrangements. FIGS. 6A and 6B show examples of complementary LEDs with base terminals 600A and 600B covering a bottom side of an LED die, and uncoupled terminals 602A and 602B arranged at an outer portion of a top side of the same LED die. Alternatively, FIGS. 7A and 7B show examples of complementary LEDs with base terminals 700A and 700B partially covering a majority of a bottom side of an LED die, and uncoupled terminals 702A and 702B arranged at an edge portion of the bottom side of the same LED die, isolated by a non-conducting gap 704A and 704B.

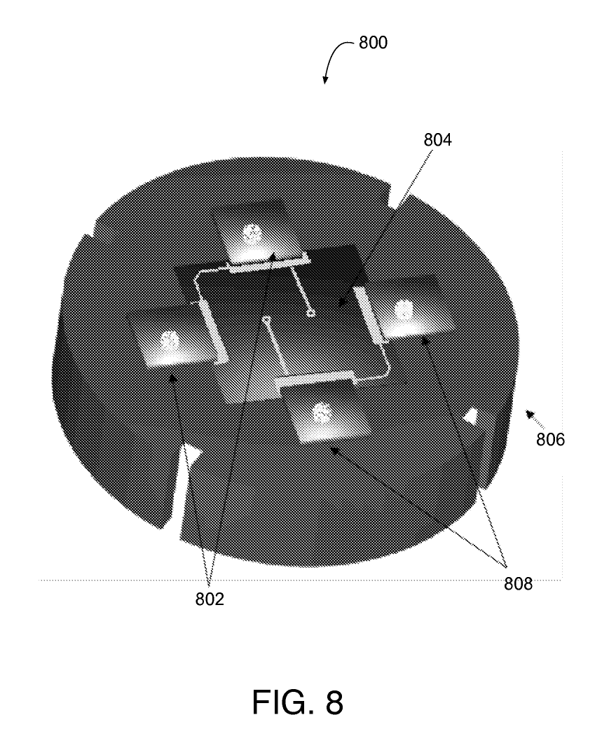

FIG. 8 shows an example of a multi-leg bridge device 800 with two pairs of complementary LEDs of the type shown in FIGS. 7A and 7B. A first leg 802 of the bridge device 800 includes two LEDs with cathode base terminals covering most of their bottom surface and isolated anode edge terminals connected by conducting paths in a PCB 804 in the center of a conducting mounting interface 806 (e.g., composed of Copper). A second leg 808 of the bridge device 800 includes two LEDs with anode base terminals covering most of their bottom surface and isolated edge terminals connected by conducting paths in the PCB 804.

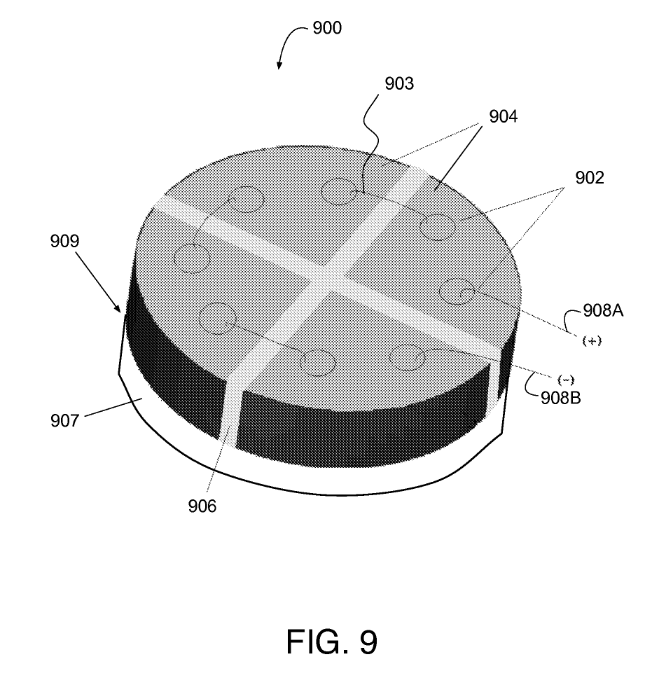

FIG. 9 shows an example of a device 900 with a plurality of metal objects 904, with electrical isolation 906 between them and with each metal object supporting complementary LEDs 902. The uncoupled terminals from the complementary LEDs on each metal object can be electrically connected to the uncoupled terminals in proper polarity of the other complementary LEDs to form higher voltage LED series arrangements. The electrical connections between uncoupled terminals of neighboring complementary LEDs can be accomplished with wires 903, or other electrical couplers such as bus bars, or a PCB, for example. Attachment of the metal objects 904 to a single heat sink 907 can be accomplished by adding a thin electrical isolation layer 909 at the interface between the metal objects 904 and the heat sink 907. Terminals 908A and 908B are connected to a power source supplying power to the LEDs.

It is to be understood that the foregoing description is intended to illustrate and not to limit the scope of the invention, which is defined by the scope of the appended claims. Other embodiments are within the scope of the following claims.

What is claimed is:

1. An apparatus, comprising:
a first light source comprising a first light emitting diode and a mounting surface electrically coupled to an anode of the first light emitting diode;
a second light source comprising a second light emitting diode and a mounting surface electrically coupled to a cathode of the second light emitting diode; and
a mounting interface having a first portion configured to support a connection to the mounting surface of the first light source at a first location on the first portion, and configured to support a connection to the mounting surface of the second light source at a second location on the first portion, with the connections providing thermal conductivity between the first portion and the mounting surface of the first light source and between the first portion and the mounting surface of the second light source, and the connections providing an electrical connection between the anode of the first light emitting diode and the cathode of the second light emitting diode.

2. The apparatus of claim 1, wherein the first portion of the mounting interface comprises an electrically conductive material.

3. The apparatus of claim 2, wherein the first portion comprises a surface of the electrically conductive material.

4. The apparatus of claim 3, wherein the first portion comprises a substantially flat surface of the electrically conductive material.

5. The apparatus of claim 3, wherein the mounting surface of the first light source and the mounting surface of the second light source are substantially flat.

6. The apparatus of claim 5, wherein the surface of the electrically conductive material has at least one bend between the first location and the second location to provide an angle between the mounting surface of the first light source and the mounting surface of the second light source.

7. The apparatus of claim 2, wherein the electrically conductive material consists essentially of metal.

8. The apparatus of claim 1, wherein the mounting interface includes a second portion that is electrically insulating and configured to electrically isolate a terminal electrically coupled to a cathode of the first light emitting diode and configured to electrically isolate a terminal electrically coupled to an anode of the second light emitting diode.

9. The apparatus of claim 8, further comprising a power source electrically coupled to: the terminal electrically coupled to the cathode of the first light emitting diode, and the terminal electrically coupled to the anode of the second light emitting diode.

10. The apparatus of claim 1, wherein the first light emitting diode is fabricated on a first surface of a first semiconductor substrate and the mounting surface of the first light source comprises a metalized surface of the first semiconductor substrate opposite to the first surface of the first semiconductor substrate, and the second light emitting diode is fabricated on a first surface of a second semiconductor substrate and the mounting surface of the second light source comprises a metalized surface of the second semiconductor substrate opposite to the first surface of the second semiconductor substrate.

11. The apparatus of claim 10, wherein the first semiconductor substrate is doped as a p-type semiconductor, and the second semiconductor substrate is doped as an n-type semiconductor.

12. The apparatus of claim 1, wherein at least one of the first light source or the second light source includes multiple light emitting diodes.

13. The apparatus of claim 1, further comprising:
a third light source comprising a third light emitting diode and a mounting surface electrically coupled to an anode of the third light emitting diode; and
a fourth light source comprising a fourth light emitting diode and a mounting surface electrically coupled to a cathode of the fourth light emitting diode;
wherein the mounting interface has multiple electrically isolated portions, including the first portion and a second portion configured to support a connection to the mounting surface of the third light source at a first location on the second portion, and configured to support a connection to the mounting surface of the fourth light source at a second location on the second portion, with the connections providing thermal conductivity between the second portion and the mounting surface of the third light source and between the second portion and the mounting surface of the fourth light source, and the connections providing an electrical connection between the anode of the third light emitting diode and the cathode of the fourth light emitting diode.

14. The apparatus of claim 13, further comprising an electrical connection between a terminal electrically coupled to the anode of the second light emitting diode and the cathode of the third light emitting diode.

15. The apparatus of claim 1, wherein the first light source, second light source, and mounting interface are included in a single surface mount package.

16. A method, comprising:
providing a mounting interface;
connecting, at a first location on a first portion of the mounting interface, a first light source comprising a first light emitting diode and a mounting surface electrically coupled to an anode of the first light emitting diode; and
connecting, at a second location on the first portion of the mounting interface, a second light source comprising a second light emitting diode and a mounting surface electrically coupled to a cathode of the second light emitting diode;
wherein the connections provide thermal conductivity between the first portion and the mounting surface of the first light source and between the first portion and the mounting surface of the second light source, and the connections provide an electrical connection between the anode of the first light emitting diode and the cathode of the second light emitting diode.

17. The method of claim 16, wherein the first portion of the mounting interface comprises an electrically conductive material.

18. The method of claim 17, wherein the first portion comprises a surface of the electrically conductive material.

19. The method of claim 18, wherein the first portion comprises a substantially flat surface of the electrically conductive material.

20. The method of claim 18, wherein the mounting surface of the first light source and the mounting surface of the second light source are substantially flat.

21. The method of claim 20, wherein the surface of the electrically conductive material has at least one bend between the first location and the second location to provide an angle between the mounting surface of the first light source and the mounting surface of the second light source.

22. The method of claim 17, wherein the electrically conductive material consists essentially of metal.

23. The method of claim 16, wherein the mounting interface includes a second portion that is electrically insulating and configured to electrically isolate a terminal electrically coupled to a cathode of the first light emitting diode and configured to electrically isolate a terminal electrically coupled to an anode of the second light emitting diode.

24. The method of claim 23, further comprising electrically coupling a power source to: the terminal electrically coupled to the cathode of the first light emitting diode, and the terminal electrically coupled to the anode of the second light emitting diode.

25. The method of claim 16, wherein the first light emitting diode is fabricated on a first surface of a first semiconductor substrate and the mounting surface of the first light source comprises a metalized surface of the first semiconductor substrate opposite to the first surface of the first semiconductor substrate, and the second light emitting diode is fabricated on a first surface of a second semiconductor substrate and the mounting surface of the second light source comprises a metalized surface of the second semiconductor substrate opposite to the first surface of the second semiconductor substrate.

26. The method of claim 25, wherein the first semiconductor substrate is doped as a p-type semiconductor, and the second semiconductor substrate is doped as an n-type semiconductor.

27. The method of claim 16, wherein at least one of the first light source or the second light source includes multiple light emitting diodes.

28. The method of claim 16, further comprising:
connecting, at a first location on a second portion of the mounting interface, a third light source comprising a third light emitting diode and a mounting surface electrically coupled to an anode of the third light emitting diode; and
connecting, at a second location on the second portion of the mounting interface, a fourth light source comprising a fourth light emitting diode and a mounting surface electrically coupled to a cathode of the fourth light emitting diode;
wherein the mounting interface has multiple electrically isolated portions, including the first portion and the second portion, and the connections provide thermal conductivity between the second portion and the mounting surface of the third light source and between the second portion and the mounting surface of the fourth light source, and the connections provide an electrical connection between the anode of the third light emitting diode and the cathode of the fourth light emitting diode.

29. The method of claim 28, further comprising electrically connecting: a terminal electrically coupled to the anode of the second light emitting diode, and the cathode of the third light emitting diode.

30. The method of claim 16, wherein the first light source, second light source, and mounting interface are fabricated in a single manufacturing process.
